(19) United States
(12) Patent Application Publication
(10) Pub. No.: US 2007/0000434 A1
(43) Pub. Date: Jan. 4, 2007

(54) Apparatuses and methods for detecting defects in semiconductor workpieces

(75) Inventor: Andrzej Buczkowski, Bend, OR (US)

Correspondence Address: PERKINS COIE LLP;PATENT-SEA, P.O. BOX 1247, SEATTLE, WA, 98111-1247, US

(73) Assignee: Accent Optical Technologies, Inc., Bend, OR (US)

(21) Appl. No.: 11/475,792

(22) Filed: Jun. 26, 2006

Related U.S. Application Data
(60) Provisional application No. 60/695,307, filed on Jun. 30, 2005.

(51) Int. Cl. C30B 23/00; C30B 25/00; C30B 28/12; C30B 28/14

(52) U.S. Cl. 117/89

(57) ABSTRACT

Non-contact methods and apparatuses for detecting defects such as pile-ups in semiconductor wafers are disclosed herein. An embodiment of one such method includes irradiating a portion of a semiconductor workpiece, measuring photoluminescence from the irradiated portion of the semiconductor workpiece, and estimating a density of defects in the irradiated portion of the semiconductor workpiece based on the measured photoluminescence.

### CROSS-REFERENCE TO RELATED APPLICATION

This application claims the benefit of U.S. Provisional Patent Application No. 60/695,307, filed Jun. 30, 2005, which is incorporated by reference herein.

### TECHNICAL FIELD

The present invention generally relates to apparatuses and methods for detecting defects such as pile-ups in semiconductor wafers.

### BACKGROUND

Semiconductor devices and other microelectronic devices are typically manufactured on a wafer having a large number of individual dies (e.g., chips). Each wafer undergoes several different procedures to construct the switches, capacitors, conductive interconnects, and other components of the devices. For example, a wafer can be processed using lithography, implanting, etching, deposition, planarization, annealing, and other procedures that are repeated to construct a high density of features. One aspect of manufacturing microelectronic devices is evaluating the wafers to ensure that wafers are within the desired specifications and do not include defects that can negatively affect the various microelectronic components that are formed in and/or on them.

FIG. 1 is an enlarged schematic side cross-sectional view of a portion of a wafer 10 having defects. The wafer 10 includes a surface 11, a silicon substrate 12, a silicon germanium layer 13a adjacent to the substrate 12, and an epitaxial layer 13b adjacent to the silicon germanium layer 13a. Formation of the layers 13a-b can create internal strain within the wafer 10 such that the crystals in the wafer 10 tend to nucleate defects such as misfit dislocations 14 (only one shown in FIG. 1) and threading arms 15 in order to relax the crystal lattice. The misfit dislocations 14 extend in a plane generally parallel to the surface 11 of the wafer 10 at a depth typically below the active region of the wafer 10 in which the devices are formed. Because the misfit dislocations 14 do not pass through the active region of the wafer 10, the misfit dislocations generally do not create defects in the devices formed on and/or in the wafer 10. The threading arms 15, however, tend to form in clusters or pile-ups 16 at the end of the misfit dislocations 14 and propagate generally toward the surface 11 of the wafer 10. As such, the threading arms 15 can pass through the device region of the wafer 10 and render devices defective. It is, therefore, desirable to detect threading arms and pile-ups in wafers so that defective wafers with high densities of pile-ups are identified and eliminated from further processing at an early stage.

One conventional method for detecting pile-ups in wafers includes directing light toward a wafer and measuring the phase shift, intensity, and other properties of the reflected light. Pile-ups create physical non-uniformities (e.g., bumps, grooves, and pits) at the surface of the wafer that alter the reflectance of the light returning from the wafer. Conventional methods using reflectance detect pile-ups by sensing patterns in the reflected light that are indicative of the non-uniformities at the surface. Misfit dislocations, however, may also create physical non-uniformities at the surface of the wafer. Accordingly, one drawback of conventional methods for detecting pile-ups is that the methods cannot accurately distinguish between pile-ups, which may render a wafer defective, and misfit dislocations, which typically are not problematic. Accordingly, there is a need to improve the process for detecting pile-ups in semiconductor wafers.

### BRIEF DESCRIPTION OF THE DRAWINGS

FIG. 1 is an enlarged schematic side cross-sectional view of a portion of a wafer having defects.

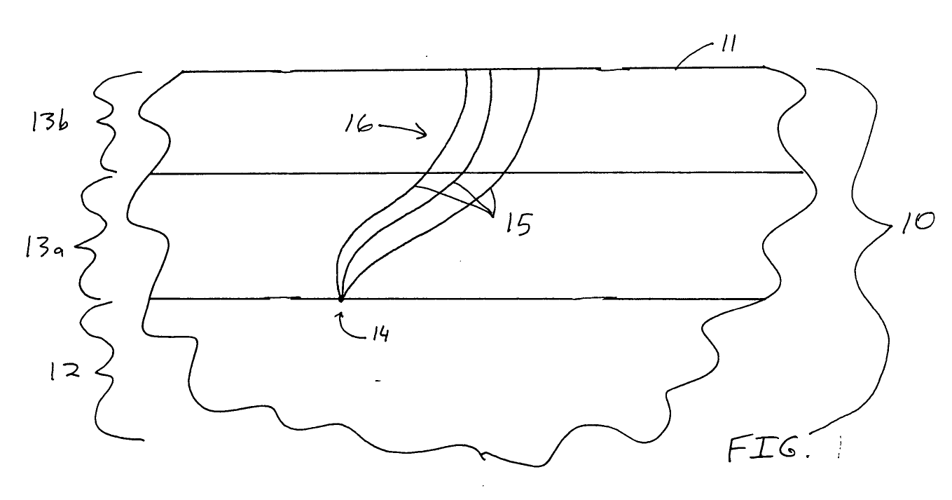

FIG. 2 is a schematic illustration of an apparatus for detecting pile-ups and other defects in a semiconductor wafer.

FIG. 3 is an enlarged schematic side cross-sectional view of a portion of the wafer with a laser beam impinging upon the wafer.

FIG. 4 is a flow chart illustrating one embodiment of a non-contact and non-destructive method for detecting pile-ups in a semiconductor wafer in accordance with the invention.

FIG. 5 is a photoluminescence image taken of a portion of a semiconductor wafer.

FIG. 6 is a flow chart illustrating an embodiment of an automatic evaluation process for detecting pile-ups in a semiconductor wafer in accordance with the invention.

FIG. 7 is an example of a mask formed from filtering the photoluminescence image illustrated in FIG. 5.

FIG. 8 is an example of a superimposed image formed by superimposing the mask of FIG. 7 onto the photoluminescence image of FIG. 5.

FIG. 9 is a flow chart illustrating one embodiment of a non-contact method for determining the density of pile-ups in a semiconductor wafer in accordance with the invention.

FIG. 10 is a top schematic view of the semiconductor wafer illustrated in FIG. 3.

### DETAILED DESCRIPTION

The following disclosure describes non-contact methods and apparatuses for detecting defects such as pile-ups in semiconductor wafers. An embodiment of one such method includes irradiating a portion of a semiconductor workpiece, measuring photoluminescence from the irradiated portion of the semiconductor workpiece, and estimating a density of defects in the irradiated portion of the semiconductor workpiece based on the measured photoluminescence.

In another embodiment, a method includes measuring photoluminescence from a portion of a semiconductor workpiece, and detecting a defect pile-up in the semiconductor workpiece based on the measured photoluminescence.

In another embodiment, a method includes irradiating a portion of a semiconductor workpiece, measuring photoluminescence emitted from the irradiated portion of the workpiece, and filtering the photoluminescence data to detect a defect extending generally transverse to a surface of the semiconductor workpiece.

In another embodiment, a method includes measuring photoluminescence from a semiconductor workpiece, and detecting a threading arm in the semiconductor workpiece by comparing the measured photoluminescence from a first section of the semiconductor workpiece to at least one of (a) the measured photoluminescence from a second section of the workpiece, or (b) a predetermined range of photoluminescence values.

Another aspect of the invention is directed to apparatuses for detecting defects in semiconductor workpieces. An embodiment of one such apparatus includes a radiation source configured to irradiate a portion of the semiconductor workpiece, a detector configured to measure photoluminescence from the semiconductor workpiece, and a controller operably coupled to the detector. The controller has a computer-readable medium containing instructions to perform at least one of the above-mentioned methods.

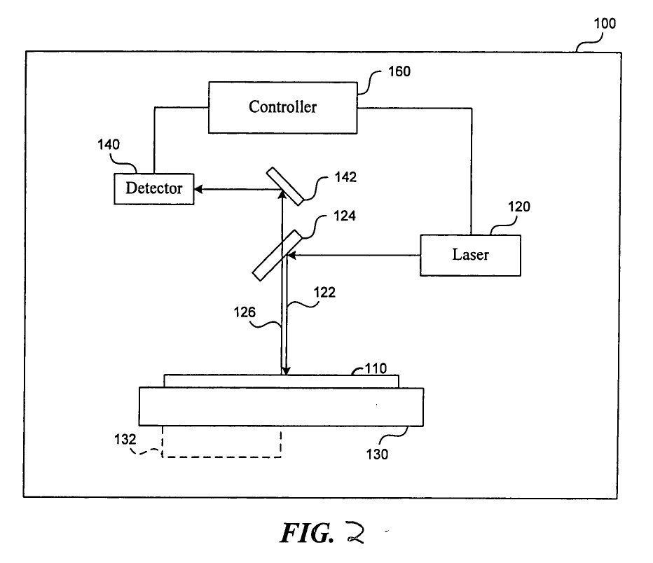

Certain details are set forth in the following description and in FIGS. 2-10 to provide a thorough understanding of various embodiments of the invention. Other details describing well-known structures and systems often associated with processing semiconductor wafers are not set forth in the following disclosure to avoid unnecessarily obscuring the description of various embodiments of the invention. Many of the details, dimensions, angles, and other features shown in the figures are merely illustrative of particular embodiments of the invention. Accordingly, other embodiments can have other details, dimensions, and/or features without departing from the present invention. In addition, further embodiments of the invention may be practiced without several of the details described below, or various aspects of any of the embodiments described below can be combined in different embodiments. Where the context permits, singular or plural terms may also include the plural or singular term, respectively. Moreover, unless the word “or” is expressly limited to mean only a single item exclusive from other items in reference to a list of at least two items, then the use of “or” in such a list is to be interpreted as including (a) any single item in the list, (b) all of the items in the list, or (c) any combination of items in the list. The term “comprising” is used throughout to mean including at least the recited feature(s) such that any greater number of the same feature and/or types of other features or components are not precluded. Additionally, the term “wafer” is defined as any substrate either by itself or in combination with additional materials that have been implanted in or otherwise deposited over the substrate.

### A. Embodiments of an Apparatus for Detecting Pile-Ups in a Semiconductor Wafer

FIG. 2 is a schematic illustration of an apparatus 100 for detecting pile-ups and other defects in a semiconductor wafer 110. The apparatus 100 detects pile-ups or other defects by exciting a population of the atoms in a portion of the semiconductor wafer 110 and measuring the photoluminescence from the excited atoms. Based on the measured photoluminescence, the apparatus 100 can detect pile-ups in the wafer 100, identify the location of the pile-ups, and/or determine the density of the pile-ups. The apparatus 100 can be a freestanding system separate from a workpiece processing tool, or the apparatus 100 can be a component of a processing tool that performs a process on the wafer 110.

In the illustrated embodiment, the apparatus 100 includes a laser 120 for producing a laser beam 122 to impinge upon a portion of the wafer 110 and effect photoluminescence 126 from the portion of the wafer 110, a detector 140 for measuring the photoluminescence 126 from the wafer 110, and a controller 160 for operating the laser 120 and the detector 140. The laser 120 is configured to produce a laser beam with a selected wavelength to penetrate the wafer 110 to a desired depth. In several applications, the laser 120 may adjust the wavelength of the laser beam 122 to penetrate different depths of the wafer 110 and effect photoluminescence 126 from different regions of the wafer 110. In other applications, however, the laser 120 may not adjust the wavelength of the laser beam 122. Moreover, in additional embodiments, the apparatus 100 may include multiple lasers that each produce a laser beam with a different wavelength. In either case, the detector 140 can include a lens, filter, and/or other optical mechanism to isolate certain wavelengths of the photoluminescence 126 and measure the photoluminescence 126 from a selected portion of the wafer 110.

The illustrated apparatus 100 further includes a beam controller 124 for directing the laser beam 122 toward one or more desired regions of the wafer 110 and a reflector 142 for directing at least some of the photoluminescence 126 from the wafer 110 toward the detector 140. The beam controller 124 can include optical fibers, a beam expander, a beam splitter, and/or other devices to direct the laser beam 122. The apparatus 100 may also include a support member 130 for carrying the wafer 110 and a positioning device 132 (shown in broken lines) for moving the support member 130 to accurately and properly position the wafer 110 relative to the laser 120 and/or beam controller 124. Suitable apparatuses are described in PCT application No. WO 98/11425, which is hereby incorporated by reference, and include the SiPHER tool manufactured by Accent Optical Technologies of Bend, Oreg. In other embodiments, the apparatus 100 may not include the beam controller 124 and/or the reflector 142. In additional embodiments, the apparatus 100 may not include a laser 120, but rather has a different mechanism for producing high intensity light to effect photoluminescence from the wafer 110.

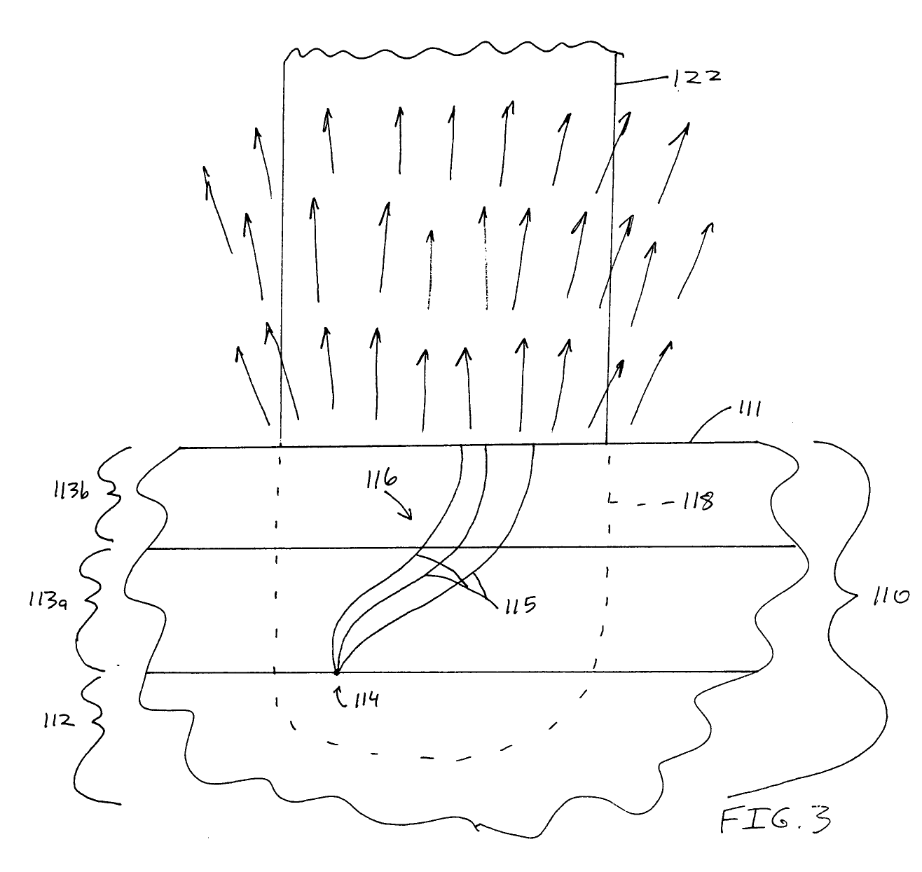

FIG. 3 is an enlarged schematic side cross-sectional view of a portion of the wafer 110 with the laser beam 122 impinging upon the wafer 110. The illustrated wafer 110 includes a surface 111, a silicon substrate 112, a silicon germanium layer 113a adjacent to the substrate 112, and an epitaxial layer 113b adjacent to the silicon germanium layer 113a. The wafer 110 further includes a plurality of misfit dislocations 114 (only one shown in FIG. 3) and a cluster of threading arms 115, which are also referred to as a pile-up 116. As explained above, the misfit dislocations 114 are located in a plane generally parallel to the surface 111 of the wafer 110 at a depth below the active region of the wafer 110, and the threading arms 115 extend between the misfit dislocations 114 and the surface 111 of the wafer 110. As such, the threading arms 115 pass through the device region of the wafer 110 and may render devices formed therein defective. The apparatus 100 is configured and operated to detect threading arms and pile-ups in wafers so that defective wafers with high densities of pile-ups are identified and eliminated from further processing at an early stage.

### B. Embodiments of Methods for Detecting Pile-Ups in a Semiconductor Wafer

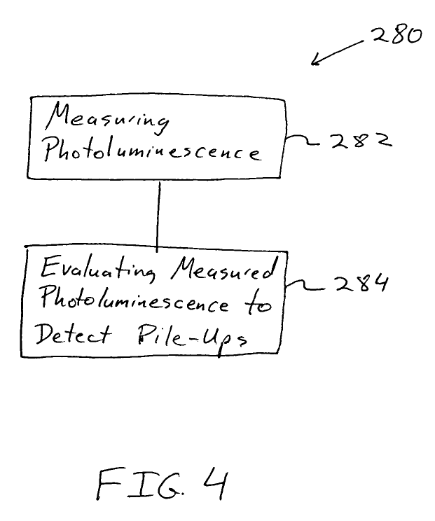

FIG. 4 is a flow chart illustrating one embodiment of a non-contact and non-destructive method 280 for detecting pile-ups in a semiconductor wafer using photoluminescence in accordance with the invention. The method 280 is particularly well suited for distinguishing between pile-ups and other defects such as misfit dislocations in semiconductor wafers. The method 280 includes a photoluminescence process 282 and an evaluation process 284. Referring to FIGS. 3 and 4, the photoluminescence process 282 includes irradiating a portion of the wafer 110 with the laser beam 122 and measuring the photoluminescence from the wafer 110. Specifically, the laser beam 122 excites a target region 118 of the wafer 110 such that electrons in the wafer 110 move from the valence band to the conductance band. When the electrons recombine (i.e., move back from the conductance band to the valence band), the electrons release energy by emitting photoluminescence in a process called radiative recombination. The electrons may also recombine without emitting photoluminescence in a process called non-radiative recombination. The misfit dislocations 114 and threading arms 115 affect the balance between radiative and non-radiative recombination. Specifically, the misfit dislocations 114 and threading arms 115 increase non-radiative recombination and reduce photoluminescence. The threading arms 115, however, increase non-radiative recombination and reduce photoluminescence to a greater extent than the misfit dislocations 114. As a result, the threading arms 115 and pile-ups 116 in the wafer 110 can be detected based on measured photoluminescence.

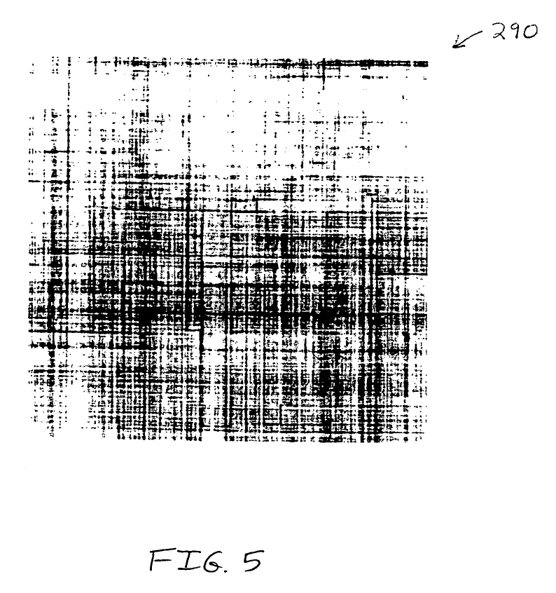

The evaluation process 284 includes detecting pile-ups 116 in the irradiated portion of the wafer 110 based on the measured photoluminescence. The evaluation process 284 can be performed manually or automatically with the controller 160 (FIG. 2) of the apparatus 100 (FIG. 2). For example, an individual can manually evaluate a photoluminescence image and identify darker regions of the image that may correspond to pile-ups. This process, however, is subjective, difficult and time-consuming. For example, FIG. 5 is a photoluminescence image 290 taken of a portion of a wafer. The intensity of the photoluminescence varies across the image 290 due to misfit dislocations, pile-ups, contaminants on the wafer, and other factors. Accordingly, the manual evaluation process is less accurate than several automated methods.

In several embodiments in which the evaluation process 284 is performed automatically, the controller 160 (FIG. 2) includes a computer-readable medium containing instructions for automatically detecting pile-ups based on the measured photoluminescence. For example, in one method, the controller 160 analyzes the intensity of photoluminescence at each pixel of the image 290 and identifies pixels with an intensity below a specific threshold as corresponding to a pile-up. Although this automated method is objective and typically more accurate than a manual process, the method does not account for contamination of the wafer or other issues that may cause a global variance in the photoluminescence intensity across the image 290.

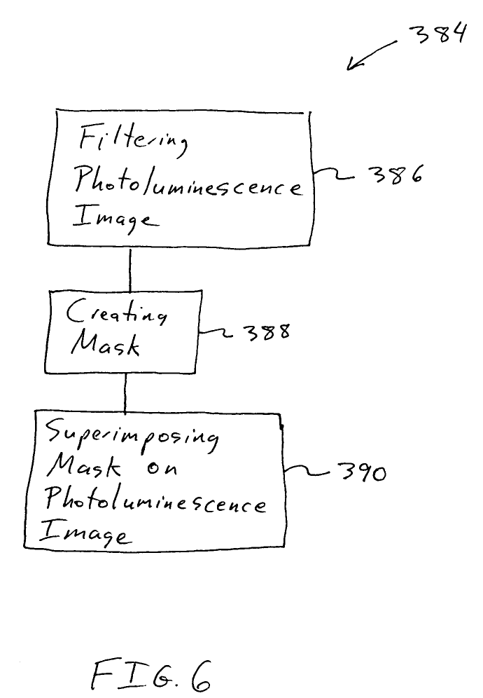

FIG. 6 is a flow chart illustrating another embodiment of an automatic evaluation process 384 for detecting pile-ups in a semiconductor wafer in accordance with the invention. The illustrated evaluation process 384 includes a filtering procedure 386, a masking procedure 388, and a superposition procedure 390. The filtering procedure 386 includes analyzing the photoluminescence gradient at the local level in the image 290 to eliminate noise and distinguish pile-ups from other types of defects in the wafer. More specifically, the controller 160 compares the photoluminescence intensity of each pixel to the photoluminescence intensity of neighboring pixels to identify abrupt changes in intensity at the local level. These sudden changes in photoluminescence intensity correspond to pile-ups. The filtering procedure 386 can be accomplished by applying a series of commonly known image processing morphological and filtering operations aimed at the enhancement of pile-ups and the suppression of the background. For example, in one embodiment tophat filtering may be used along with block averaging, image closing and/or background subtraction operations. Then, an adaptive thresholding procedure can be used for creating a mask. In additional embodiments, other algorithms can be used to filter a photoluminescence image and obtain the pile-up mask.

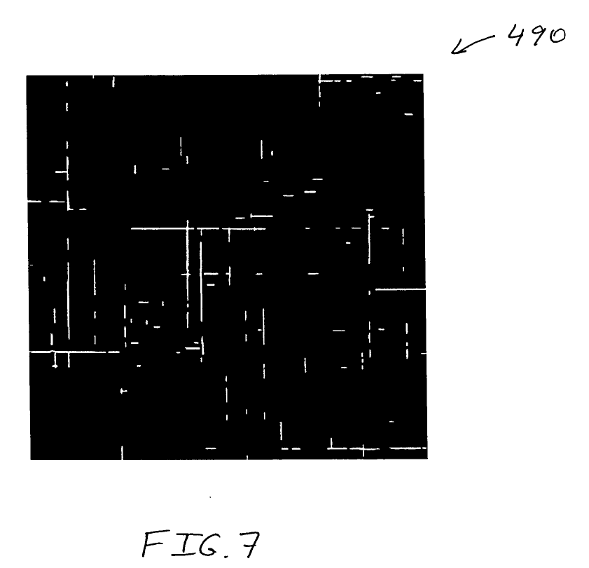

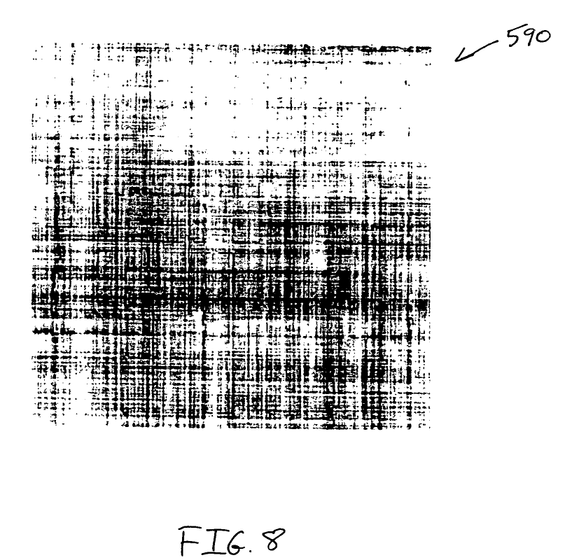

The masking procedure 388 includes creating a mask based on the results of the filtering procedure 386. Specifically, if a pixel in the photoluminescence image is determined to identify a pile-up, that pixel is represented with a 1 in the mask, and if a pixel in the photoluminescence image is determined not to identify a pile-up, that pixel is represented with a 0 in the mask. FIG. 7 is an example of a mask 490 formed by filtering the photoluminescence image 290 illustrated in FIG. 5. The dark portions of the mask 490 represent the 0s and correspond to the locations in the image 290 that do not identify pile-ups. The light portions of the mask 490 represent the 1s and correspond to the locations in the image 290 that identify pile-ups. The superposition procedure 390 includes superimposing a mask onto a photoluminescence image to generate a superimposed image. FIG. 8 is an example of a superimposed image 590 formed by superimposing the mask 490 onto the photoluminescence image 290. The illustrated superimposed image 590 includes optically distinguishable areas illustrating the precise location of the pile-ups.

One feature of the methods illustrated in FIGS. 2-8 is that the apparatus 100 can accurately detect pile-ups in semiconductor wafers without having to measure the reflectance of light from the wafers or use destructive testing methods. Rather, the apparatus 100 irradiates portions of the wafers, measures the photoluminescence from the irradiated portions, and detects pile-ups based on the measured photoluminescence. Because of the difference in electrical activity between pile-ups and misfit dislocations, the apparatus 100 can accurately distinguish between (a) pile-ups and (b) misfit dislocations and other types of defects in semiconductor wafers. This is expected to provide better results than conventional reflectance-based methods that cannot accurately distinguish between problematic pile-ups and benign misfit dislocations.

### C. Embodiments of Methods for Determining the Density of Pile-Ups in a Semiconductor Wafer

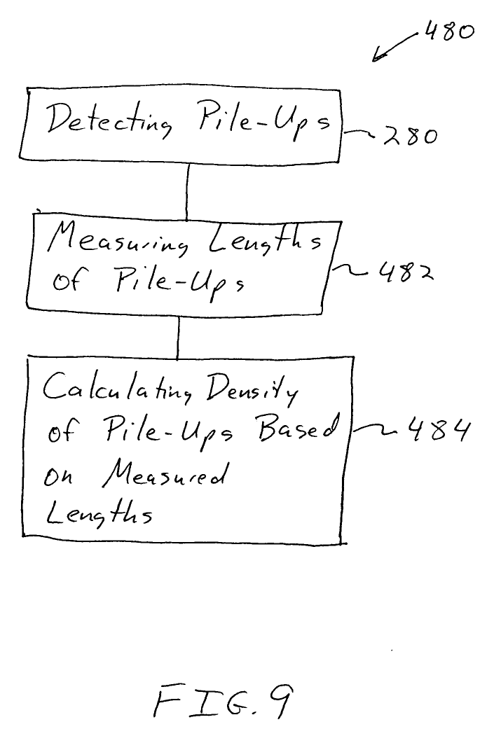

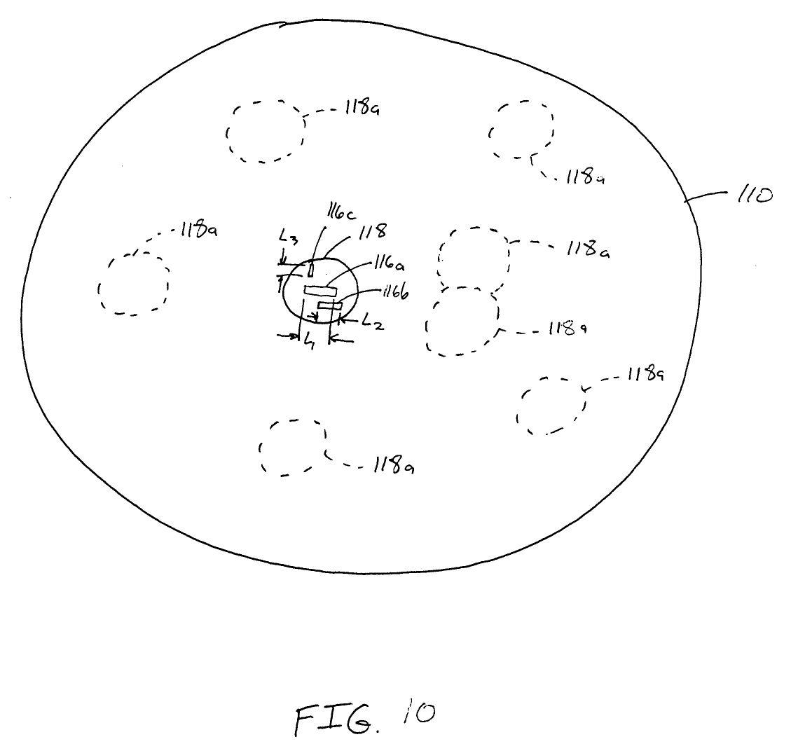

FIG. 9 is a flow chart illustrating one embodiment of a non-contact method 480 for determining the density of pile-ups in a semiconductor wafer in accordance with the invention. The illustrated method 480 includes a detecting procedure 280, a measuring procedure 482, and a calculating procedure 484. The detecting procedure 280 can be similar to the method 280 for detecting pile-ups in semiconductor wafers described above with reference to FIGS. 4-8. The measuring procedure 482 includes measuring the length of each individual pile-up detected during the detecting procedure 280. The lengths of the pile-ups are measured in a plane generally parallel to the surface of the wafer. For example, FIG. 10 is a top schematic view of the wafer 110 illustrated in FIG. 3 with a schematic photoluminescence image of the excited region 118. Within the excited region 118 of the wafer 110, a first pile-up 116 has a first length L₁, a second pile-up 116b has a second length L₂, and a third pile-up 116c has a third length L₃. Referring back to FIG. 9, the measuring procedure 482 can be performed automatically by the controller 160 (FIG. 2), for example, after generating a mask or superimposed image. Alternatively, the measuring procedure 482 can be performed manually after identifying the pile-ups on a photoluminescence image, mask, and/or superimposed image.

The calculating procedure 484 includes summing the lengths of all identified pile-ups and determining an area of the analyzed portion of the wafer. The calculating procedure 484 further includes dividing the total length of the pile-ups by the area of the analyzed portion to calculate the density of pile-ups. The density of the pile-ups is accordingly calculated by the following formula:
D=L/A
in which
D represents the density of pile-ups within an analyzed portion of a wafer;
L represents the total length of the identified pile-ups in the analyzed portion; and
A represents the area of the analyzed portion.

One feature of the method illustrated in FIGS. 2-10 is that the apparatus 100 can accurately determine the density of pile-ups in semiconductor wafers. An advantage of this feature is that the apparatus 100 can compare the pile-up density in a wafer to a predetermined range of acceptable pile-up densities to determine whether the wafer is within specification. As such, the process provides a fast quality control test for eliminating defective wafers from further processing at an early stage.

Referring only to FIG. 10, the apparatus 100 can effect and measure photoluminescence from one region, multiple regions, or the entire wafer 110 in detecting pile-ups and determining pile-up density. For example, in several applications, the apparatus 100 may excite only a single region 118 of the wafer 110 and measure the photoluminescence from that single region 118. Data obtained from the single region 118 can be used to estimate the density of pile-ups in the wafer 110. Alternatively, the apparatus 100 may excite multiple regions 118a (shown in broken lines) of the wafer 110 and measure the photoluminescence from the multiple regions 118a. In such embodiments, the multiple regions 118a can be excited simultaneously or sequentially.

From the foregoing, it will be appreciated that specific embodiments of the invention have been described herein for purposes of illustration, but that various modifications may be made without deviating from the invention. For example, aspects of the invention described in the context of particular embodiments may be combined or eliminated in other embodiments. Accordingly, the invention is not limited except as by the appended claims.

I/We claim:

1. A non-contact method of detecting defects in a semiconductor workpiece, the method comprising:
irradiating a portion of a semiconductor workpiece;
measuring photoluminescence from the irradiated portion of the semiconductor workpiece; and
estimating a density of defects in the irradiated portion of the semiconductor workpiece based on the measured photoluminescence.

2. The method of claim 1 wherein estimating the density of defects comprises determining the density of defects based on an area of the irradiated portion of the semiconductor workpiece and a dimension of the individual defects in a plane generally parallel to a surface of the semiconductor workpiece.

3. The method of claim 1 wherein estimating the density of defects comprises:
determining a length of the individual defects in a plane generally parallel to a surface of the semiconductor workpiece;
summing the lengths of the individual defects;
estimating an area of the irradiated portion of the semiconductor workpiece;
and
dividing the summed length of the individual defects by the estimated area.

4. The method of claim 1 wherein estimating the density of defects comprises detecting a defect pile-up in the irradiated portion of the semiconductor workpiece.

5. The method of claim 1 wherein estimating the density of defects comprises detecting a plurality of threading arms in the semiconductor workpiece.

6. The method of claim 1 wherein estimating the density of defects comprises:
filtering the photoluminescence data to detect pile-ups in the semiconductor workpiece;
generating a mask based on the filtered photoluminescence data; and
determining a dimension of at least one pile-up based on the mask.

7. The method of claim 1 wherein the individual defects extend in a direction generally transverse to a surface of the semiconductor workpiece.

8. The method of claim 1 wherein estimating the density of defects comprises filtering the photoluminescence data to detect pile-ups in the semiconductor workpiece.

9. The method of claim 1 wherein the individual defects extend from a dislocation within the semiconductor workpiece to a surface of the workpiece.

10. The method of claim 1, further comprising comparing the estimated density of defects with a predetermined range of acceptable defect densities for the semiconductor workpiece.

11. The method of claim 1 wherein estimating the density of defects comprises determining the density of defects without analyzing a reflectance of light from the semiconductor workpiece.

12. The method of claim 1 wherein irradiating the portion of the semiconductor workpiece comprises directing a laser beam toward the portion of the workpiece.

13. A non-contact method of detecting defects in a semiconductor workpiece, the method comprising:
measuring photoluminescence from a portion of a semiconductor workpiece; and
detecting a defect pile-up in the semiconductor workpiece based on the measured photoluminescence.

14. The method of claim 13 wherein detecting the defect pile-up comprises filtering the photoluminescence data to detect the defect pile-up.

15. The method of claim 13, further comprising estimating a density of defects in the semiconductor workpiece based detected defect pile-up.

16. The method of claim 13 wherein detecting the defect pile-up comprises:
filtering the photoluminescence data; and
generating a mask based on the filtered photoluminescence data.

17. The method of claim 13 wherein detecting the defect pile-up comprises detecting a dislocation pile-up extending in a direction generally transverse to a surface of the semiconductor workpiece.

18. The method of claim 13 wherein:
measuring photoluminescence comprises generating an image with a plurality of pixels; and
detecting the defect pile-up comprises determining a photoluminescence gradient between at least one pixel and neighboring pixels of the at least one pixel.

19. A non-contact method of detecting defects in a semiconductor workpiece, the method comprising:
irradiating a portion of a semiconductor workpiece;
measuring photoluminescence emitted from the irradiated portion of the workpiece; and
filtering the photoluminescence data to detect a defect extending generally transverse to a surface of the semiconductor workpiece.

20. The method of claim 19 wherein:
measuring photoluminescence comprises generating an image with a plurality of pixels; and
filtering the photoluminescence data comprises determining a photoluminescence gradient between at least one pixel and neighboring pixels of the at least one pixel.

21. The method of claim 19, further comprising generating a mask based on the filtered photoluminescence data.

22. The method of claim 19, further comprising estimating a density of defects in the semiconductor workpiece based on the filtered photoluminescence data.

23. The method of claim 19, further comprising:
determining a length of the defect in a plane generally parallel to the surface of the workpiece;
estimating an area of the irradiated portion of the semiconductor workpiece; and
calculating a density of defects in the semiconductor workpiece based on the area of the irradiated portion and the length of the defect.

24. A non-contact method of detecting defects in a semiconductor workpiece, the method comprising:
measuring photoluminescence from a semiconductor workpiece; and
detecting a threading arm in the semiconductor workpiece by comparing the measured photoluminescence from a first section of the semiconductor workpiece to at least one of (a) the measured photoluminescence from a second section of the workpiece, or (b) a predetermined range of photoluminescence values.

25. The method of claim 24, further comprising estimating a density of defects in the semiconductor workpiece based on the measured photoluminescence.

26. The method of claim 24, further comprising determining a dimension of a defect pile-up in a plane generally parallel to a surface of the semiconductor workpiece, wherein the defect pile-up comprises the threading arm.

27. The method of claim 24 wherein detecting a threading arm comprises detecting a dislocation pile-up extending in a direction generally transverse to a surface of the semiconductor workpiece.

28. An apparatus for detecting defects in a semiconductor workpiece, the apparatus comprising:
a radiation source configured to irradiate a portion of the semiconductor workpiece;
a detector configured to measure photoluminescence from the semiconductor workpiece; and
a controller operably coupled to the detector, the controller having a computer-readable medium containing instructions to perform a method comprising—
irradiating a portion of the semiconductor workpiece;
measuring photoluminescence from the irradiated portion of the semiconductor workpiece; and
estimating a density of defects in the irradiated portion of the semiconductor workpiece based on the measured photoluminescence.

29. The apparatus of claim 28 wherein the radiation source comprises a laser configured to direct a laser beam toward the semiconductor workpiece.

30. The apparatus of claim 28 wherein the instructions for estimating the density of defects comprise determining the density of defects based on an area of the irradiated portion and a dimension of the individual defects in a plane generally parallel to a surface of the semiconductor workpiece.

31. The apparatus of claim 28 wherein the instructions for estimating the density of defects comprise detecting a defect pile-up in the irradiated portion of the semiconductor workpiece.

32. An apparatus for detecting defects in a semiconductor workpiece, the apparatus comprising:
a radiation source configured to irradiate a portion of the semiconductor workpiece;
a detector configured to measure photoluminescence from the semiconductor workpiece; and
a controller operably coupled to the detector, the controller having a computer-readable medium containing instructions to perform a method comprising—
measuring photoluminescence from the semiconductor workpiece; and
detecting a defect pile-up in the semiconductor workpiece based on the measured photoluminescence.

33. The apparatus of claim 32 wherein the radiation source comprises a laser configured to direct a laser beam toward the semiconductor workpiece.

34. The apparatus of claim 32 wherein the instructions for detecting the defect pile-up comprise filtering the photoluminescence data to detect the defect pile-up.

35. An apparatus for detecting defects in a semiconductor workpiece, the apparatus comprising:
a radiation source configured to irradiate a portion of the semiconductor workpiece;
a detector configured to measure photoluminescence from the semiconductor workpiece; and
a controller operably coupled to the detector, the controller having a computer-readable medium containing instructions to perform a method comprising—
irradiating the portion of the semiconductor workpiece;
measuring photoluminescence emitted from the irradiated portion of the workpiece; and
filtering the photoluminescence data to detect a defect extending generally transverse to a surface of the semiconductor workpiece.

36. The apparatus of claim 35 wherein the radiation source comprises a laser configured to direct a laser beam toward the semiconductor workpiece.

37. The apparatus of claim 35 wherein:
the instructions for measuring photoluminescence comprise instructions for generating an image with a plurality of pixels; and
the instructions for filtering the photoluminescence data comprise instructions for determining a photoluminescence gradient between at least one pixel and neighboring pixels of the at least one pixel.

38. An apparatus for detecting defects in a semiconductor workpiece, the apparatus comprising:
means for measuring photoluminescence from a portion of a semiconductor workpiece; and
means for detecting a threading arm in the semiconductor workpiece based on measured photoluminescence.

39. The apparatus of claim 38 wherein the means for detecting the threading arm comprise a controller having a computer-readable medium containing instructions to perform a method including filtering the photoluminescence data to detect the threading arm.

40. The apparatus of claim 38, further comprising means for irradiating the portion of the semiconductor workpiece.
